(19) United States
(12) Patent Application Publication
(10) Pub. No.: US 2026/0177959 A1
(43) Pub. Date: Jun. 25, 2026

(54) IMAGE FORMING APPARATUS, CONTROL METHOD, AND NON-TRANSITORY COMPUTER-READABLE RECORDING MEDIUM

(71) Applicant: KONICA MINOLTA, INC., Tokyo (JP)

(72) Inventor: Tatsutoshi YAMADA, Toyokawa-shi (JP)

(73) Assignee: KONICA MINOLTA, INC., Tokyo (JP)

(21) Appl. No.: 19/369,014

(22) Filed: Oct. 24, 2025

(30) Foreign Application Priority Data
Dec. 25, 2024 (JP) 2024-228261

(51) Int. Cl. G03G 15/00; G01R 19/165; G03G 15/08; G03G 15/20; H02K 7/14

(52) U.S. Cl. CPC G03G 15/5004; G01R 19/16571; G03G 15/0808; G03G 15/0849; G03G 15/0891; G03G 15/2017; G03G 15/2064; G03G 15/5016; G03G 15/5075; G03G 15/55; G03G 15/757; G03G 15/80; H02K 7/14

(57) ABSTRACT

An image forming apparatus includes a power supply unit that supplies power to a plurality of loads, a current detector that detects a total current value supplied from the power supply, a storage section that stores, for each operating state of the plurality of loads, a current reference value of a current that flows through the plurality of loads, and a controller that controls, during driving of the plurality of loads, to compare the total current value with the current reference value, to determine whether any of the plurality of loads is abnormal, and to stop operation of the plurality of loads when determining that any of the plurality of loads is abnormal. When stopping the operation of the plurality of loads, the controller compares the total current value with the current reference value while stopping the plurality of loads one by one, thereby identifying a load having an abnormality.

### CROSS REFERENCE TO RELATED APPLICATIONS

This application is based on Japanese Patent Application No. 2024-228261 filed in Japanese on Dec. 25, 2024, the contents of which are incorporated herein by reference.

### BACKGROUND OF THE INVENTION

### Technical Field

The present invention relates to an image forming apparatus, a control method, and a non-transitory computer-readable recording medium.

### Description Of Related Art

An image forming apparatus such as an MFP (Multifunction Peripheral) is equipped with a plurality of loads such as a motor for driving a conveyance mechanism for conveying a sheet, a motor for driving a photoreceptor, a motor for driving a developing device, and a motor for replenishing toner. The image forming apparatus is also equipped with a load such as a fan in addition to the motors.

Conventionally, there has been proposed an image forming apparatus that diagnoses an abnormality of a load by detecting a current flowing through the load and comparing the detected current value with a reference value. Such image forming apparatuses are disclosed in, for example, Patent Literature 1 (JP1993-26937A), Patent Literature 2 (JP2006-330506A), and Patent Literature 3 (JP2007-233285A).

For example, an image forming apparatus disclosed in Patent Literature 1 supplies a control signal to a plurality of controlled objects and detects an amount of current flowing through the controlled objects in response to a change in the control signal. This image forming apparatus determines whether it is normal or not based on the detected amount of current, and if it is abnormal, cuts off the power supply to the apparatus.

However, in the image forming apparatus of Patent Literature 1, when a plurality of loads are simultaneously operating at the time of detection of the current amount, even if an abnormality can be detected based on the detected current amount, it is not possible to identify which of the plurality of loads has an abnormality.

An image forming apparatus disclosed in Patent Literature 2 stores a unit standard value which is a standard of current consumption at a predetermined timing for each of a plurality of functional units. The image forming apparatus acquires a current consumption value at a predetermined timing, compares it with a unit standard value, and determines that an abnormality has occurred when there is a difference of a predetermined value or more. Further, when the image forming apparatus determines that an abnormality has occurred in a certain functional unit, the image forming apparatus sequentially drives loads belonging to the functional unit one by one, compares a current flowing through the load with a load standard value, and determines whether or not there is an abnormality in the load being driven.

However, when the image forming apparatus of Patent Literature 2 determines that there is an abnormality in a functional unit including a plurality of loads, the image forming apparatus temporarily stops the functional unit and then sequentially drives the plurality of loads one by one. Therefore, this image forming apparatus has a problem in that it takes time to identify an abnormal load.

The image forming apparatus disclosed in Patent Literature 3 detects an abnormality by detecting a current flowing through a plurality of fan motors and comparing the detected current value with a specified value. Therefore, the image forming apparatus can detect that there is an abnormality in any of the plurality of fan motors.

However, the image forming apparatus of Patent Literature 3 cannot identify which of the plurality of fan motors has an abnormality.

### SUMMARY OF THE INVENTION

The present invention has been devised in order to solve the above-described conventional problems. That is, an object of the present invention is to provide an image forming apparatus, a control method, and a non-transitory computer-readable recording medium capable of, in a case where there is an abnormality in any of a plurality of operating loads, identifying the load having the abnormality earlier than ever before.

One subject of the present invention is directed to an image forming apparatus. According to an aspect of the present invention, an image forming apparatus includes: a power supply unit that supplies power to a plurality of loads; a current detector that detects a total current value supplied from the power supply to the plurality of loads; a storage section that stores, for each operating state of the plurality of loads, a current reference value of a current that flows through the plurality of loads when each of the plurality of loads is normal; and a controller that controls, during driving of the plurality of loads, to compare the total current value detected by the current detector with the current reference value, to determine whether or not any of the plurality of loads is abnormal, and to stop operation of the plurality of loads when determining that any of the plurality of loads is abnormal. When stopping the operation of the plurality of loads, the controller compares the total current value detected by the current detector with the current reference value for each of the operating states of the plurality of loads while stopping the plurality of loads one by one, thereby identifying a load having an abnormality.

### BRIEF DESCRIPTION OF THE DRAWINGS

The advantages and features provided by one or more embodiments of the invention will become more fully understood from the detailed description given herein below and the appended drawings which are given by way of illustration only, and thus are not intended as a definition of the limits of the present invention.

FIG. 1 is a diagram illustrating an example of the configuration of an image forming apparatus;

FIG. 2 is a block diagram illustrating a control mechanism in the image forming apparatus;

FIG. 3 is a diagram illustrating an example of the reference value information;

FIG. 4 is a diagram illustrating an example of order information;

FIG. 5 is a timing chart showing an example of load stop processing when an abnormality is detected in a state in which a plurality of loads are operating;

FIG. 6 is a flowchart illustrating an example of a processing procedure performed in the controller

FIG. 7 is a flowchart illustrating an example of load stop processing;

FIG. 8 is a flowchart illustrating an example of load stop processing;

FIG. 9 is a diagram illustrating an example of a notification screen displayed on the display part of the operation panel;

FIG. 10 is a timing chart illustrating an example of load stop processing in a case where both loads of the operating time set load and the stop order set load are operating;

FIG. 11 is a timing chart showing an example of the load stop processing when the conveyance motor is in operation; and

FIG. 12 is a timing chart showing an example of the load stop processing when the fixing motor is in operation.

### DETAILED DESCRIPTION OF EMBODIMENTS

Hereinafter, one or more embodiments of the present invention will be described with reference to the drawings. However, the scope of the invention is not limited to the disclosed embodiments. Note that in the embodiments described below, common elements are denoted by the same reference signs, and redundant description thereof is omitted.

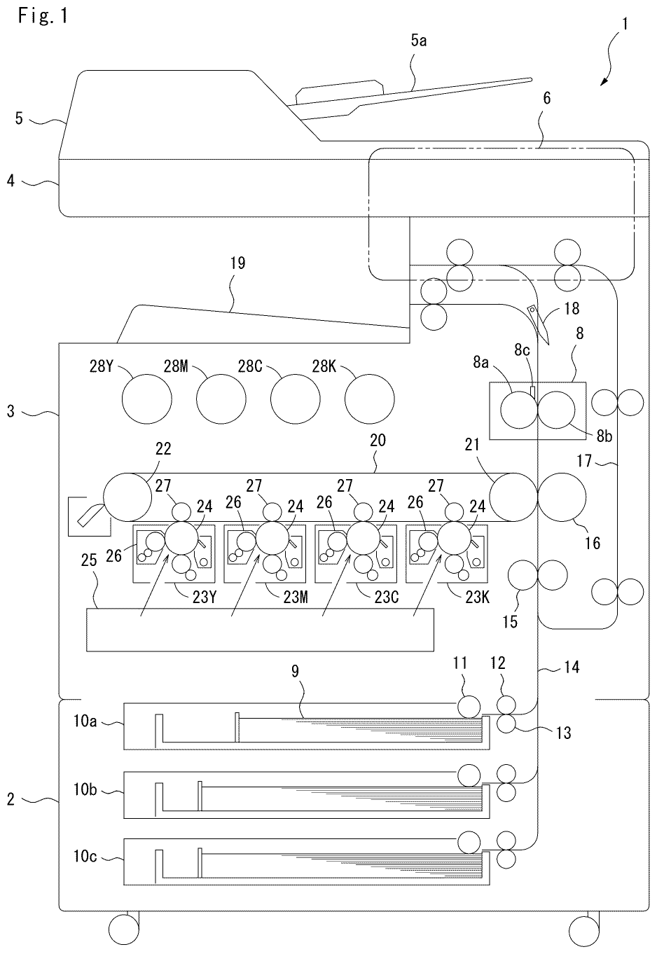

FIG. 1 is a diagram illustrating an example of an internal configuration of an image forming apparatus 1 according to an embodiment of the present invention. The image forming apparatus 1 is, for example, an MFP in which a plurality of functions such as a copy function, a print function, and an image reader function are integrated. The image forming apparatus 1 includes a sheet feed and conveyance section 2 and an image forming section 3 in a lower part of an apparatus main body, and includes a scanner section 4 and an automatic document feeder (ADF) 5 in an upper part of the apparatus main body. Furthermore, the image forming apparatus 1 includes, on the front side of the apparatus main body, an operation panel 6 that can be operated by a user.

The scanner section 4 and the automatic document feeder 5 operate when a document is read by the copy function and the image reader function. The scanner section 4 and the automatic document feeder 5 automatically read an image of a document set by a user and generate image data. The automatic document feeder 5 includes a document tray 5a on which a document is placed. When a plurality of documents are set on the document tray 5a, the automatic document feeder 5 takes out the uppermost document one by one from the plurality of documents, and automatically conveys the document toward an image reading position by the scanner section 4. The scanner section 4 performs image reading in conjunction with a document conveyance operation by the automatic document feeder 5, and automatically reads an image of a document automatically conveyed by the automatic document feeder 5 to generate image data.

sheet feed and conveyance section 2 and the image forming section 3 operate at the time of image formation by the copy function and the print function. The sheet feed and conveyance section 2 feeds and conveys sheets 9 such as printing sheet one by one. The image forming section 3 forms an image based on image data to be printed on the sheet 9 conveyed by the sheet feed and conveyance section 2.

The sheet feed and conveyance section 2 includes a plurality of sheet feed trays 10a, 10b, and 10c, and the sheets 9 are accommodated in each of the sheet feed trays 10a, 10b, and 10c. The sheet feed trays 10a, 10b, and 10c may accommodate sheets 9 of different types or different sizes. The sheet feed and conveyance section 2 feeds the sheets 9 stored in the sheet feed trays 10a, 10b, and 10c one by one toward the conveyance path 14 on the downstream side. Therefore, the sheet feed and conveyance section 2 includes a pickup roller 11, a sheet feed roller 12, and a separation roller 13. For example, in a case of feeding a sheet 9 stored in the sheet feed tray 10a, the sheet feed and conveyance section 2 rotationally drives a pickup roller 11 and a sheet feed roller 12 provided in the sheet feed tray 10a. As a result, the uppermost one of the plurality of sheets 9 accommodated in the sheet feed tray 10a is supplied to the conveyance path 14 on the downstream side.

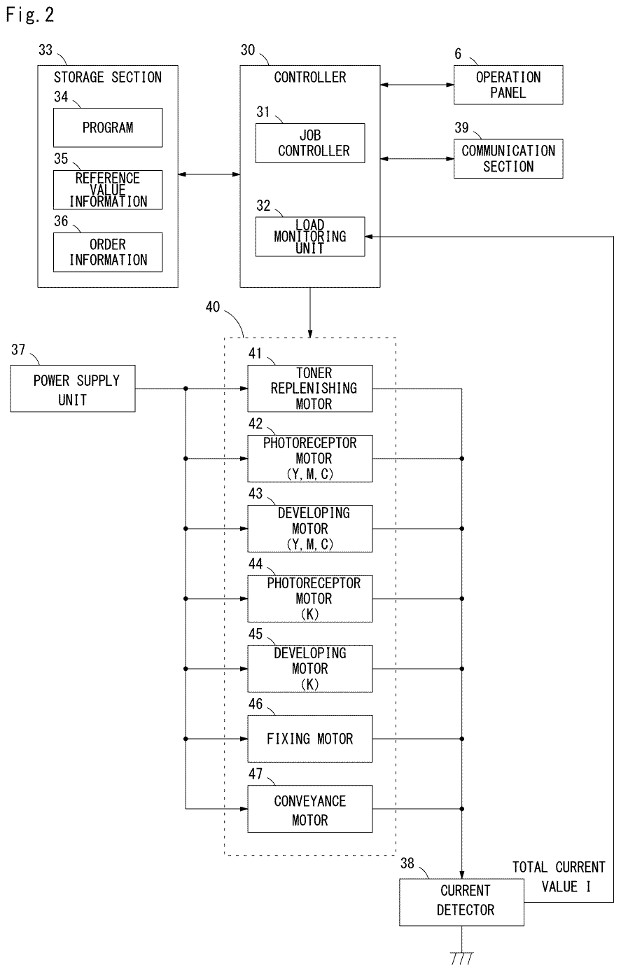

The conveyance path 14 is provided with a registration roller 15, a secondary transfer roller 16, and the fixing section 8. The registration roller 15 corrects skew of the sheet 9 fed from the sheet feed and conveyance section 2, and feeds the sheet 9 to the secondary transfer roller 16 at a predetermined timing. The secondary transfer roller 16 secondarily transfers the toner image, which has been primarily transferred to the intermediate transfer belt 20 in the image forming section 3, to one side of the sheet 9, thereby forming an image on the one side of the sheet 9. The sheet 9 onto which the toner image has been secondarily transferred by the secondary transfer roller 16 then passes through the fixing section 8, by which the toner image is fixed. The fixing section 8 includes fixing rollers including, for example, a heating roller 8a and a pressure roller 8b. The fixing section 8 fixes the toner image to the sheet 9 by sandwiching the sheet 9 between the heating roller 8a and the pressure roller 8b and performing a heating process and a pressing process. The heating roller 8a and the pressure roller 8b are rotationally driven by a fixing motor 46 (see FIG. 2) which will be described later.

Furthermore, the fixing section 8 includes a heating roller 8a on the downstream side of a nip part formed by the pressure roller 8b and the peeling member 8c. The peeling member 8c is a claw-shaped member, peels off the sheet 9, which is in close contact with the heating roller 8a, from the heating roller 8a, and feeds the sheet 9 toward the downstream side of the conveyance path 14.

Further, the conveyance path 14 includes a reversing path 17 for reversing both sides of the sheet 9 in order to form an image on the back surface of the sheet 9. A switching member 18 that switches a conveyance destination of the sheet 9 having an image formed on one surface thereof is provided on the downstream side of the fixing section 8. The switching member 18 switches the conveyance route of the sheet 9 to one of the sheet ejection tray 19 and the reversing path 17 on the downstream side of the fixing section 8. For example, when double-sided printing is designated in the print job, the sheet feed and conveyance section 2 drives the switching member 18 so that the conveyance route of the sheet 9 becomes the reversing path 17. Then, the sheet feed and conveyance section 2 guides the sheet 9 having passed through the fixing section 8 to the reversing path 17, and conveys the sheet 9 again to the registration roller 15 in a state where the front and back of the sheet 9 are reversed.

Each roller that conveys the sheet 9 along the conveyance path 14 is rotationally driven by a conveyance motor 47 (see FIG. 2), which will be described later.

The image forming section 3 includes an intermediate transfer belt 20 wound around a driving roller 21 and a driven roller 22. The intermediate transfer belt 20 is configured as an endless belt, and circulates between the driving roller 21 and the driven roller 22 as the driving roller 21 rotates. The driving roller 21 is provided at a position facing the secondary transfer roller 16. The intermediate transfer belt 20 circularly moves in a state of being nipped between the driving roller 21 and the secondary transfer roller 16.

Image forming units 23Y, 23M, 23C, and 23K are disposed below the intermediate transfer belt 20. The image forming units 23Y, 23M, 23C, and 23K are units that primarily transfer toner images of Y (yellow), M (magenta), C (cyan), and K (black), respectively, to the intermediate transfer belt 20. For example, the image forming units 23Y, 23M, and 23C for colors (Y, M, and C) are disposed in this order at positions on an upstream side in a movement direction of the intermediate transfer belt 20. Furthermore, the image forming unit 23K for black (K) is disposed at the most downstream position in the movement direction of the intermediate transfer belt 20.

Each of the image forming units 23Y, 23M, 23C, and 23K includes a drum-shaped photoreceptor 24 as an image bearing member. The photoreceptor 24 is rotationally driven in a predetermined direction (clockwise direction) by later-described photoreceptor motors 42 and 44 (see FIG. 2).

A cleaning section and a charging device are disposed around the photoreceptor 24. Further, below the image forming units 23Y, 23M, 23C, and 23K, an exposure device 25 that exposes the photoreceptor 24 of each of the image forming units 23Y, 23M, 23C, and 23K is provided. Furthermore, a developing device 26 is provided around the photoreceptor 24. The developing device 26 includes a developing roller that supplies a developer containing toner to the surface of the photoreceptor 24, and is driven by developing motors 43 and 45 (see FIG. 2) to be described later.

The image forming units 23Y, 23M, 23C, and 23K form electrostatic latent images on the surfaces of the photoreceptor 24 by charging the surfaces of the photoreceptor 24 with a predetermined charge by the charging device and then exposing the surfaces of the photoreceptor 24 by the exposure devices 25. Thereafter, the developing device 26 applies a developer to the surface of the photoreceptor 24, thereby developing the electrostatic latent image with the toner. Thus, a toner image is formed on the surface of the photoreceptor 24.

The photoreceptor 24 on which the toner image is formed comes into contact with the intermediate transfer belt 20. At this joining position, a primary transfer roller 27 is arranged with the intermediate transfer belt 20 in between. The primary transfer roller 27 primarily transfers a toner image formed on the photoreceptor 24 to the intermediate transfer belt 20 by an applied transfer voltage. The image forming units 23Y, 23M, 23C, and 23K form a color image on the intermediate transfer belt 20 by primarily transferring toner images of the respective colors onto the intermediate transfer belt 20 in a superimposed manner. When the toner image primarily transferred to the intermediate transfer belt 20 passes through the position of the secondary transfer roller 16, the toner image is secondarily transferred to the surface of the sheet 9 supplied by the registration roller 15.

Toner bottles 28Y, 28M, 28C, and 28K of respective colors of Y, M, C, and K are provided on an upper part of the intermediate transfer belt 20. The toner bottles 28Y, 28M, 28C, and 28K contain developing materials containing toners of respective colors. In each of the image forming units 23Y, 23M, 23C, and 23K, as the toner concentration in the developing device 26 decreases, the toner bottle 28Y, 28M, 28C, or 28K is rotationally driven to perform a toner supply operation of supplying toner to the developing device 26. Through this toner replenishing operation, the toner concentration in the developing device 26 is maintained at a predetermined concentration. Note that when the toner replenishing operation is performed, a toner replenishing motor 41 (see FIG. 2) which will be described later is driven.

FIG. 2 is a block diagram illustrating a control mechanism in the image forming apparatus 1. The image forming apparatus 1 includes the operation panel 6, a controller 30, a storage section 33, a power supply unit 37, a current detector 38, a communication section 39, and a plurality of loads 40.

The plurality of loads 40 include a toner replenishing motor 41, a photoreceptor motor 42 for color, a developing motor 43 for color, a photoreceptor motor 44 for K, a developing motor 45 for K, a fixing motor 46, and a conveyance motor 47. The toner replenishing motor 41 performs a toner replenishing operation by rotating the toner bottles 28Y, 28M, 28C, and 28K. The photoreceptor motor 42 for color rotates the photoreceptor 24 provided in the image forming units 23Y, 23M, and 23C. The color developing motor 43 drives the developing devices 26 provided in the image forming units 23Y, 23M, and 23C to supply the Y, M, and C toners to the surfaces of the photoreceptors 24. The photoreceptor motor 44 for K rotates the photoreceptor 24 provided in the image forming unit 23K. The developing motor 45 for K drives the developing device 26 provided in the image forming unit 23K to supply K toner onto the face of the photoreceptor 24. The fixing motor 46 rotationally drives the heating roller 8a and the pressure roller 8b of the fixing section 8. The conveyance motor 47 rotationally drives various rollers provided in the conveyance path 14.

It should be noted that the image forming apparatus 1 actually has more loads. However, in the present embodiment, in order to simplify the description, a case where seven motors shown in FIG. 2 are included in the plurality of loads 40 will be described as an example.

The power supply unit 37 supplies power to the plurality of loads 40. The current detector 38 detects a total current value I supplied from the power supply unit 37 to the plurality of loads 40. The plurality of loads 40 are connected in parallel to the power supply unit 37 and the current detector 38. When at least one of the plurality of loads 40 is operating, the current detector 38 detects a total current value I supplied from the power supply unit 37 to the operating load. The current detector 38 outputs the detected total current value I to the controller 30.

The controller 30 integrally controls the operation of the image forming apparatus 1. The controller 30 includes a hardware processor such as a CPU (not illustrated), and reads and executes a program 34 stored in the storage section 33. Thus, the controller 30 functions as a job controller 31 and a load monitoring unit 32. The controller 30 is connected to each of the plurality of loads 40 and controls the operation of each of the plurality of loads 40. The controller 30 is connected to the operation panel 6, the storage section 33, and the communication section 39.

The storage section 33 is a nonvolatile storage device constituted by a hard disk drive (HDD) or a solid state drive (SSD). The storage section 33 stores a program 34 to be executed by the hardware processor of the controller 30. The storage section 33 stores reference value information 35 and order information 36.

The communication section 39 connects the image forming apparatus 1 to a network such as a local area network (LAN) and performs communication via the network. The controller 30 can communicate with an external device via the communication section 39.

Job controller 31 controls execution of a job in image forming apparatus 1. For example, when the job controller 31 receives a print job via the communication section 39, the job controller 31 drives the sheet feed and conveyance section 2 and the image forming section 3 to control an operation of printing and outputting an image on the sheet 9. At this time, the job controller 31 controls the operation of each of the plurality of loads 40. The job controller 31 also controls the operation of each of the plurality of loads 40 when a copy job is executed in the image forming apparatus 1.

For example, in a case where a color image is formed on the sheet 9, the job controller 31 operates each of the photoreceptor motor 42 for color, the color developing motor 43, the photoreceptor motor 44 for K, the developing motor 45 for K, the fixing motor 46, and the conveyance motor 47. Further, when a monochrome image is formed on the sheet 9, the job controller 31 operates each of the photoreceptor motor 44 for K, the developing motor 45 for K, the fixing motor 46, and the conveyance motor 47.

Furthermore, for example, when the toner concentration decreases in the developing device 26 of any of the image forming units 23Y, 23M, 23C, and 23K during execution of a print job, the job controller 31 drives the toner replenishing motor 41. At this time, the job controller 31 specifies the developing device 26 to be supplied with toner, and drives the toner replenishing motor 41. Thus, toner is supplied from the toner bottle 28Y, 28M, 28C, or 28K to the specified developing device 26, and the toner concentration in the developing device 26 is maintained at a predetermined concentration.

The load monitoring unit 32 monitors the operation states of the loads 40 when the loads 40 are operating. The load monitoring unit 32 acquires the total current value I detected by the current detector 38 when at least one of the plurality of loads 40 is operating. The load monitoring unit 32 determines, based on the total current value I, whether the operating load has an abnormality. At this time, the load monitoring unit 32 reads the reference value information 35 from the storage section 33, and refers to the reference value information 35 to determine whether the total current value I is abnormal.

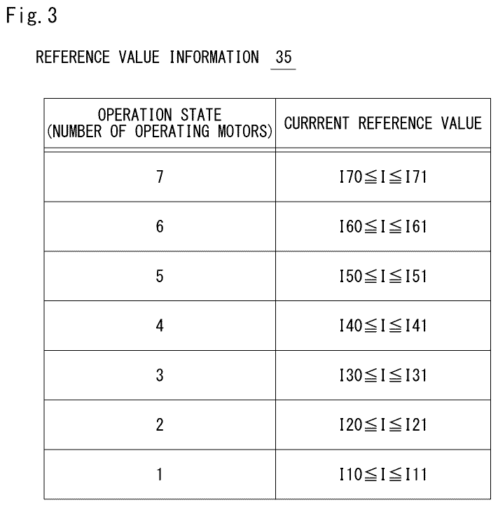

FIG. 3 is a diagram showing an example of the reference value information 35. The reference value information 35 is information in which a current reference value indicating a range of a normal total current value is recorded for each operating state of the plurality of loads 40. The operating states of the plurality of loads 40 change according to the number of operating loads (motors). Therefore, a current reference value is registered in the reference value information 35 in accordance with the number of operating loads (motors). For example, in an operating state in which all of the seven motors are operating, a range from the current I70 to the current I71 is registered as the current reference value. In an operating state in which the six motors are operating, a range from a current I60 to a current I61 is registered as the current reference value. In an operating state in which the five motors are operating, a range from a current I50 to a current I51 is registered as the current reference value. In an operating state in which the four motors are operating, a range from a current I40 to a current I41 is registered as the current reference value. In an operating state in which the three motors are operating, a range from a current I30 to a current I31 is registered as the current reference value. In an operating state in which the two motors are operating, a range from a current I20 to a current I21 is registered as the current reference value. In an operating state in which one motor is operating, a range from the current I10 to the current I11 is registered as the current reference value.

Note that the currents flowing through the plurality of loads 40 may be different from each other. In such a case, the reference value information 35 may be information in which a current reference value is registered for each combination of operating loads.

When the plurality of loads 40 are operating, the load monitoring unit 32 detects the operating states of the loads. That is, the load monitoring unit 32 detects the number of operating loads (motors) among the plurality of loads 40. Then, the load monitoring unit 32 refers to the reference value information 35 and acquires the current reference value corresponding to the detected operation state. Upon acquiring the total current value I from the current detector 38, the load monitoring unit 32 compares the total current value I with a current reference value to determine whether any of the plurality of loads 40 that are currently operating has an abnormality. Specifically, when the total current value I detected by the current detector 38 is within the range of the current reference value, the load monitoring unit 32 determines that none of the plurality of loads 40 that are currently operating has an abnormality. On the other hand, when the total current value I detected by the current detector 38 is not within the range of the current reference value, the load monitoring unit 32 determines that any of the plurality of loads 40 that are currently operating has an abnormality.

When determining that any of the plurality of loads 40 in operation has an abnormality, the load monitoring unit 32 stops the operation of the plurality of loads 40. At this time, when the job is being executed, the load monitoring unit 32 forcibly interrupts the execution of the job and stops the operation of the loads 40.

For example, in a case where the total current value I is not within the range of the current reference value when one load among the plurality of loads 40 is operating, the load monitoring unit 32 can specify that the one load that is operating is abnormal. However, if the total current value I is not within the range of the current reference value when two or more loads among the plurality of loads 40 are operating, the load monitoring unit 32 cannot identify which of the two or more loads is abnormal.

Therefore, when the load monitoring unit 32 determines that there is an abnormality in any of the plurality of loads 40, the load monitoring unit 32 performs a process of specifying the load having the abnormality in a load stop process of stopping the operation of the plurality of loads 40. That is, when the load monitoring unit 32 stops the operation of the plurality of loads 40, the load monitoring unit 32 sequentially stops the plurality of loads 40 one by one. Each time one load is stopped, the load monitoring unit 32 repeats the process of comparing the total current value I detected by the current detector 38 with the current reference value in the operating state and determining whether or not there is an abnormality. When one load is stopped, if the total current value I is within the range of the current reference value, the load monitoring unit 32 can identify that an abnormality has occurred in the stopped load. Therefore, the load monitoring unit 32 can specify one load in which an abnormality has occurred in the execution process of the load stop process for stopping the plurality of loads 40.

The plurality of loads 40 include a stop order setting load in which the order of stopping the operation at the time of abnormality is set in advance. For example, the photoreceptor motor 42 for color, the developing motor 43 for color, the photoreceptor motor 44 for K, and the developing motor 45 for K are loads for which the stop order is set. The stop order of these stop order setting loads is described in the order information 36.

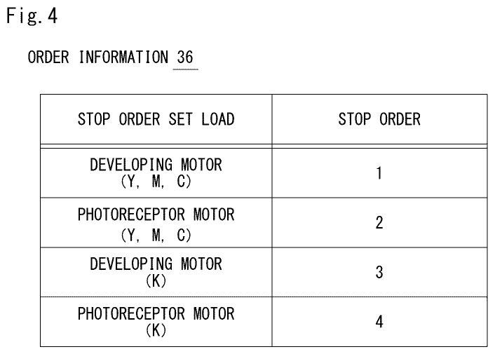

FIG. 4 is a view illustrating an example of the order information 36. In the order information 36, a stop sequence for a plurality of stop sequence-set loads is set. In the example of FIG. 4, the stop order of the developing motor 43 for color is set as first. The stop order of the photoreceptor motor 42 for color is set as second. The stop order of the developing motor 45 for K is set as third. The stop order of the photoreceptor motor 44 for K is set as the fourth.

Here, the reason why the load related to the colors (Y, M, and C) is stopped earlier than the load related to black (K) is due to the arrangement positions of the image forming units 23Y, 23M, 23C, and 23K. That is, the color (Y, M, C) image forming units 23Y, 23M, and 23C are arranged on the upstream side of the black (K) image forming unit 23K in the movement direction of the intermediate transfer belt 20. Therefore, by stopping the load for driving the color image forming units 23Y, 23M, and 23C first, the amount of toner consumption can be suppressed.

The reason why the developing motors 43 and 45 are stopped earlier than the photoreceptor motors 42 and 44 is to early stop the supply of toner to the photoreceptor 24. Stopping the developing motors 43 and 45 earlier than the photoreceptor motors 42 and 44 can reduce the consumption of toner.

The plurality of loads 40 also include a load for which the stop order is not set. When the loads for which the stop order is not set are operating, the load monitoring unit 32 basically stops the loads for which the stop order is not set in order after preferentially stopping the loads for which the stop order is set. However, as will be described later, there may be a case where there is a load to be stopped preferentially to the stop order setting load.

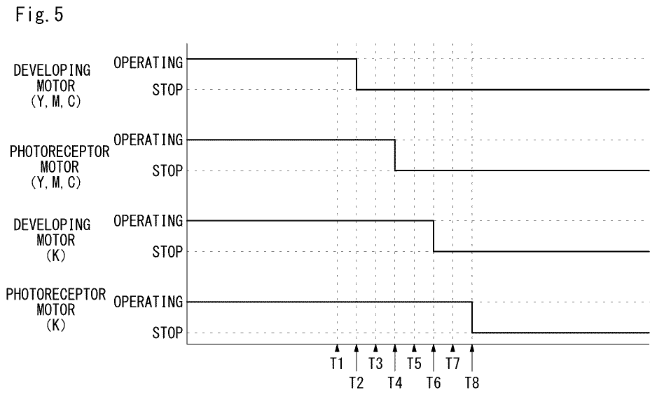

FIG. 5 is a timing chart showing an example of load stop processing when an abnormality is detected in a state in which the plurality of loads 40 are operating. FIG. 5 illustrates a state in which a plurality of loads 40 including four loads of the photoreceptor motor 42 for color, the developing motor 43 for color, the photoreceptor motor 44 for K, and the developing motor 45 for K are operating. When the plurality of loads 40 are operating, the load monitoring unit 32 monitors the operating states of the plurality of loads 40 based on the total current value I detected by the current detector 38.

For example, at the timing T1, when the load monitoring unit 32 determines that there is an abnormality in any one of the plurality of loads 40, the load monitoring unit 32 preferentially stops the four loads, for which the stopping order is set, one by one in order. At this time, the load monitoring unit 32 reads the order information 36 and determines the stop order of the four loads. The load monitoring unit 32 stops the developing motor 43 for color at a timing T2. When the developing motor 43 for color is stopped, the load monitoring unit 32 acquires the total current value I of the current flowing through the plurality of loads 40 currently operating at the timing T3 and determines whether or not the total current value I is within the range of the current reference value in the current operating state. When the total current value I is not within the range of the current reference value, there is an abnormal load among the plurality of loads 40 that are currently operating.

Next, the load monitoring unit 32 stops the photoreceptor motor 42 for color at a timing T4. When the photoreceptor motor 42 for color is stopped, the load monitoring unit 32 acquires the total current value I flowing in the plurality of loads 40 currently operating at the timing T5, and determines whether or not the total current value I is within the range of the current reference value in the current operating state. When the total current value I is not within the range of the current reference value, there is an abnormal load among the plurality of loads 40 that are currently operating.

Next, the load monitoring unit 32 stops the developing motor 45 for K at timing T6. When the developing motor 45 for K is stopped, the load monitoring unit 32 acquires the total current value I of the current flowing through the plurality of loads 40 currently operating at the timing T7 and determines whether or not the total current value I is within the range of the current reference value in the current operating state. When the total current value I is not within the range of the current reference value, there is an abnormal load among the plurality of loads 40 that are currently operating. For example, when only the photoreceptor motor 44 for K is operating at timing T7, the load monitoring unit 32 determines that the photoreceptor motor 44 for K has an abnormality. Next, the load monitoring unit 32 stops the photoreceptor motor 44 for K at the timing T8.

In addition, in a case where the total current value I is within the range of the current reference value at the timing T7, the load monitoring unit 32 specifies that there is an abnormality in the developing motor 45 for K which is stopped at the timing T6. In this case, the load monitoring unit 32 simultaneously stops all the loads that are currently operating at the timing T8.

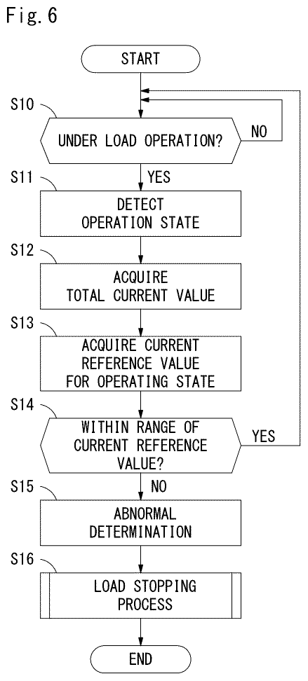

FIGS. 6 to 8 are flowcharts illustrating an example of a processing procedure performed in the controller 30. This processing is mainly performed in the load monitoring unit 32 of the controller 30. When starting this process, the controller 30 determines whether or not any of the plurality of loads 40 is in operation (step S10). Then, the controller 30 waits until any one of the loads is in operation (NO in step S10). When the plurality of loads 40 start operating in the image forming apparatus 1 (YES in step S10), the controller 30 detects the operation states of the plurality of loads 40 (step S11). At this time, the controller 30 detects an operating load among the plurality of loads 40. When a job such as a print job is executed in the image forming apparatus 1, generally, two or more loads included in the plurality of loads 40 start operating. In addition, during execution of a job such as a print job, a load to be operated among the plurality of loads 40 may be sequentially changed. Therefore, the controller 30 specifies two or more loads that are operating at the present time and detects the operation states of the plurality of loads 40.

Upon detection of the operating state, the controller 30 acquires the total current value I in the current operating state (step S12). That is, the controller 30 acquires the total current value I from the current detector 38. The controller 30 reads the reference value information 35 from the storage section 33, and acquires the current reference value corresponding to the current operating state from the reference value information 35 (step S13). Then, the controller 30 determines whether or not the total current value I detected by the current detector 38 is within the range of the current reference value corresponding to the current operation state (step S14).

When the total current value I is within the range of the current reference value (YES in step S14), the process by the controller 30 returns to step S10. Next, the controller 30 repeats the processing in steps S10 to S14. That is, when the plurality of loads 40 are operating in the image forming apparatus 1, the controller 30 repeatedly determines whether or not an abnormality has occurred based on the total current value I.

When the total current value I is not within the range of the current reference value (NO in step S14), the controller 30 determines that there is an abnormality in any one of the plurality of loads 40 that are currently operating (step S15). At this time, if two or more loads included in the plurality of loads 40 are operating, the controller 30 cannot identify which load is abnormal among the two or more loads. Therefore, when the controller 30 determines that there is an abnormality in any of the plurality of loads 40, the controller 30 executes a load stopping process (step S16). The load stop processing (step S16) is processing of sequentially stopping the plurality of loads 40 that are currently operating one by one and determining whether or not the stopped load has an abnormality.

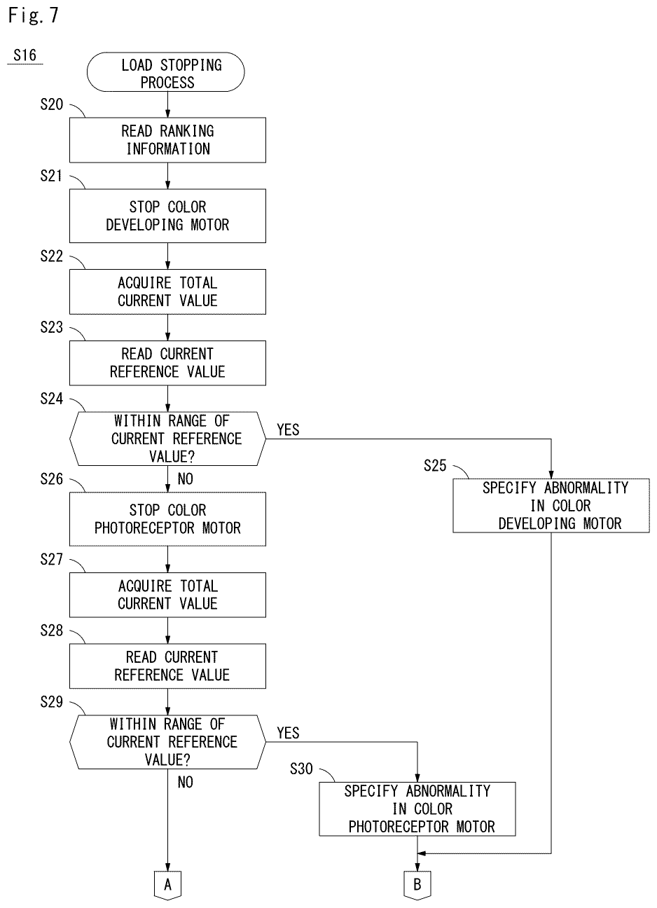

FIG. 7 is a flowchart illustrating an example of the load suspension processing (step S16). FIG. 7 illustrates load stop processing in a case where, as illustrated in FIG. 5, a plurality of loads 40 including four loads of the photoreceptor motor 42 for color, the developing motor 43 for color, the photoreceptor motor 44 for K, and the developing motor 45 for K are operating.

When starting the load suspension processing, the controller 30 reads the order information 36 from the storage section 33 (step S20). Then, the controller 30 determines the stop order of the currently operating loads based on the order information 36. Specifically, the controller 30 determines to stop the developing motor 43 for color, the photoreceptor motor 42 for color, the developing motor 45 for K, and the photoreceptor motor 44 for K one by one in this order.

Next, the controller 30 stops the developing motor 43 for color (step S21). Upon stopping the developing motor 43, the controller 30 acquires the total current value I from the current detector 38 (step S22). Furthermore, the controller 30 reads a current reference value corresponding to the current operating state from the reference value information 35 (step S23). Then, the controller 30 compares the total current value I in the state where the developing motor 43 is stopped with the reference current value, and determines whether or not the total current value I is within the range of the reference current value (step S24).

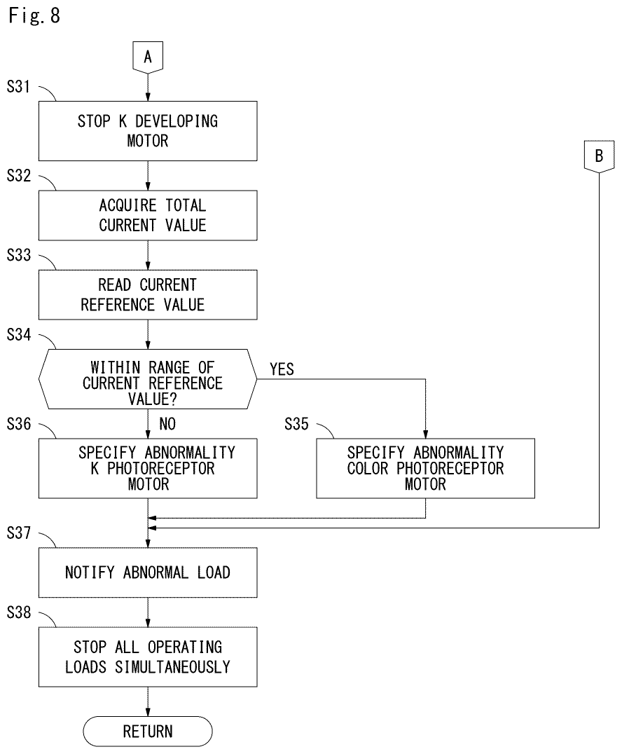

If the total current value I is within the range of the reference current values (YES in step S24), the controller 30 determines that the developing motor 43 for color stopped in step S21 has an abnormality (step S25). Then, the process by the controller 30 proceeds to step S37 in FIG. 8.

When the total current value I is not within the range of the reference current value (NO in step S24), the controller 30 next stops the photoreceptor motor 42 for color (step S26). Upon stopping the photoreceptor motor 42, the controller 30 acquires the total current value I from the current detector 38 (step S27). Furthermore, the controller 30 reads a current reference value corresponding to the current operating state from the reference value information 35 (step S28). Then, the controller 30 compares the total current value I in the state where the photoreceptor motor 42 is stopped with the reference current value, and determines whether or not the total current value I is within the range of the reference current value (step S29).

In a case where the total current value I is within the range of the reference current value (YES in step S29), the controller 30 specifies that there is an abnormality in the photoreceptor motor 42 of the color stopped in step S26 (step S30). Then, the process by the controller 30 proceeds to step S37 in FIG. 8.

When the total current value I is not within the range of the reference current value (NO in step S29), the processing by the controller 30 proceeds to the flowchart of FIG. 8. Next, the controller 30 stops the developing motor 45 for K (step S31). Upon stopping the developing motor 45, the controller 30 acquires the total current value I from the current detector 38 (step S32). Furthermore, the controller 30 reads a current reference value corresponding to the current operating state from the reference value information 35 (step S33). Then, the controller 30 compares the total current value I in the state where the developing motor 45 is stopped with the reference current value, and determines whether or not the total current value I is within the range of the reference current value (step S34).

In a case where the total current value I is within the range of the reference current value (YES in step S34), the controller 30 specifies that there is an abnormality in the developing motor 45 for K which is stopped in step S31 (step S35). On the other hand, in a case where the total current value I is not within the range of the reference current value (NO in step S34), the controller 30 specifies that there is an abnormality in the photoreceptor motor 44 for K which is currently operating (step S36).

Next, the controller 30 provides notification of the load determined to have an abnormality (step S37). At this time, the controller 30 displays a notification screen on the display part of the operation panel 6. Accordingly, the user can recognize the load in which the abnormality has occurred among the plurality of loads 40 provided in the image forming apparatus 1. In addition, the controller 30 may notify the external device of the abnormal load via the communication section 39. The external device is, for example, a server device of a service center. By sending the notification to the external device, the external device can arrange the maintenance work of the image forming apparatus 1.

Thereafter, the controller 30 collectively stops the loads that are currently operating (step S38). Thus, it is possible to prevent the load in which the abnormality has occurred from continuing to operate.

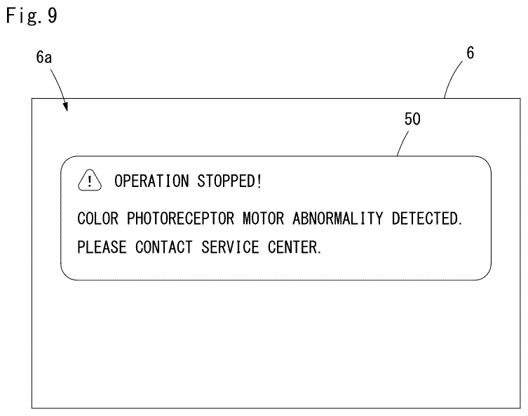

FIG. 9 is a diagram illustrating an example of a notification screen 50 displayed on the display part 6a of the operation panel 6. Upon identifying a load having an abnormality, the controller 30 displays a notification screen 50 as illustrated in FIG. 9 on the display part 6a. An example in which an abnormality has been detected in the photoreceptor motor 42 for color is illustrated in the notification screen 50 illustrated in FIG. 9. When the notification screen 50 as illustrated in FIG. 9 is displayed on the operation panel 6, the user can recognize the load in which the abnormality has occurred. The user may also recognize that he needs to contact a service center.

The plurality of loads 40 shown in FIG. 2 include an operating time setting load whose operating time is set in advance. For example, the operation time (driving time) of the toner replenishing motor 41 is set in advance in order to maintain the toner concentration in the developing device 26 at a predetermined concentration. When the operation time of the toner replenishing motor 41 is shorter than a preset time or longer than a preset time, the donor concentration in the developing device 26 cannot be maintained at a predetermined concentration. Therefore, the toner replenishing motor 41 is one of the operating time setting loads.

When determining that the total current value I is not within the range of the current reference value, if the operating time set load included in the plurality of loads 40 is operating, the controller 30 determines the stop timing of the operating time set load based on the operating time set in advance. At this time, the controller 30 determines the stop timing of the operating time set load in preference to the stop order of the stop order-set load. Therefore, when a plurality of the loads for which the stop order is set are operating, the controller 30 may cause a timing at which the load for which the operating time is set is stopped to interrupt the stop order of the loads for which the stop order is set, the stop order being determined based on the order information 36.

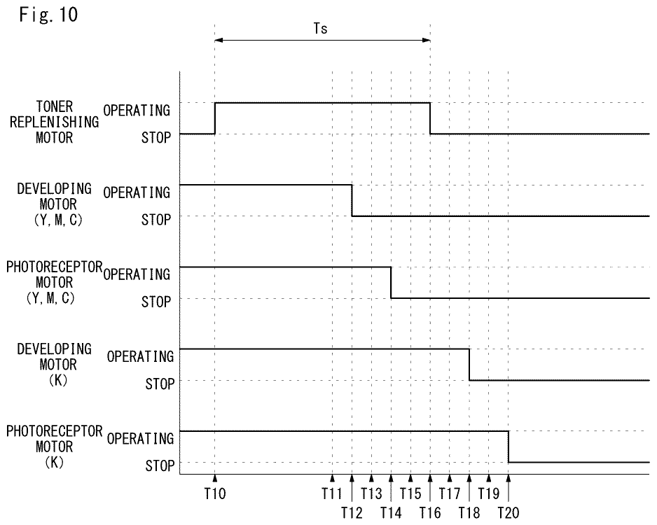

FIG. 10 is a timing chart showing an example of the load stop process when both of the operating time setting load and the stop order setting load are operating. In the example illustrated in FIG. 10, in a state where the photoreceptor motors 42 and 44 and the developing motors 43 and 45 are operating, the toner replenishing motor 41 that is an operating time setting load starts operating at the timing T10 and starts the toner replenishing operation to the developing device 26. For example, when the operation of the toner replenishing motor 41 is started at the timing T10, the controller 30 sets the operation time Ts of the toner replenishing motor 41. In the example of FIG. 10, the toner replenishing motor 41 starts operating at timing T10 and continues operating until timing T16. In this state, the load monitoring unit 32 of the controller 30 monitors the operating states of the plurality of loads 40.

After the toner replenishing motor 41 starts operating, the controller 30 determines that any of the loads has an abnormality, for example, at a timing T11. In this case, the controller 30 determines whether or not there is an abnormality in the stopped loads by comparing the total current value I with the current reference value while sequentially stopping the four loads for which the stop order is set one by one. At this time, when the operating time Ts of the toner replenishing motor 41 ends, the controller 30 preferentially stops the toner replenishing motor 41.

To be more specific, the controller 30 stops the developing motor 43 for color at timing T12. Upon stopping the developing motor 43 for color, the controller 30 acquires the total current value I of the current flowing through the plurality of loads 40 currently operating at the timing T13 and determines whether the total current value I is within the range of the reference current value for the current operating state. When the total current value I is within the range of the current reference value, the controller 30 determines that the stopped developing motor 43 is an abnormal load. On the other hand, when the total current value I is not within the range of the current reference value, the controller 30 determines that there is an abnormal load among the plurality of loads 40 that are currently operating.

Next, the controller 30 stops the photoreceptor motors 42 for color at timing T14. When the photoreceptor motor 42 for color is stopped, the controller 30 acquires the total current value I of the current flowing through the plurality of loads 40 currently operating at the timing T15 and determines whether the total current value I is within the range of the reference current value for the current operating state. In a case where the total current value I is within the range of the current reference value, the controller 30 determines that the stopped photoreceptor motor 42 is an abnormal load. On the other hand, when the total current value I is not within the range of the current reference value, the controller 30 determines that there is an abnormal load among the plurality of loads 40 that are currently operating.

Next, the controller 30 stops the toner replenishing motor 41 at a timing T16 when the operating time Ts of the toner replenishing motor 41 ends. That is, the controller 30 stops the toner replenishing motor 41 preferentially in the order set in the order information 36. Thus, the toner concentration in the developing device 26 is maintained at a predetermined concentration. Upon stopping the toner replenishing motor 41, the controller 30 acquires the total current value I of the current flowing through the plurality of loads 40 currently operating at the timing T17 and determines whether the total current value I is within the range of the reference current value in the current operating state. When the total current value I is within the range of the current reference value, the controller 30 determines that the stopped toner replenishing motor 41 is an abnormal load. On the other hand, when the total current value I is not within the range of the current reference value, the controller 30 determines that there is an abnormal load among the plurality of loads 40 that are currently operating.

Next, the controller 30 stops the developing motor 45 for K at a timing T18. Upon stopping the developing motor 45 for K, the controller 30 acquires, at the timing T19, the total current value I of the current flowing through the plurality of loads 40 that are currently operating, and determines whether the total current value I is within the range of the reference current value for the current operating state. When the total current value I is within the range of the current reference value, the controller 30 determines that the stopped developing motor 45 is an abnormal load. On the other hand, when the total current value I is not within the range of the current reference value, the controller 30 determines that there is an abnormal load among the plurality of loads 40 that are currently operating. At this time, if only the photoreceptor motor 44 for K is operating, the controller 30 determines that the photoreceptor motor 44 for K is an abnormal load. Next, the controller 30 stops the photoreceptor motor 44 for K at timing T20.

As described above, when the operating time set load is included in the plurality of loads 40 that are operating, the controller 30 sequentially stops the plurality of loads 40 one by one while maintaining the operating time Ts of the operating time set load. Therefore, if there is no abnormality in the operating time setting load, the operation by the operating time setting load is appropriately finished, and no trouble occurs.

In addition, when the controller 30 sequentially stops the plurality of loads 40 in operation, it is preferable to preferentially stop the conveyance motor 47 if the transport operation of the sheet 9 is being performed. When the conveyance motor 47 is forcibly stopped, the conveyance of the sheet 9 is stopped in the conveyance path 14. In a situation in which the plurality of loads 40 are sequentially stopped, when the stop timing of the conveyance motor 47 is delayed, the sheet 9 being conveyed is buckled, and a bellows jam may occur in the conveyance path 14. It is difficult to remove the sheet 9 having the accordion jam from the conveyance path 14, which leads to a decrease in work efficiency. Therefore, when the conveyance motor 47 is included in the plurality of loads 40 that are in operation, the controller 30 preferably stops the conveyance motor 47 preferentially over the other loads.

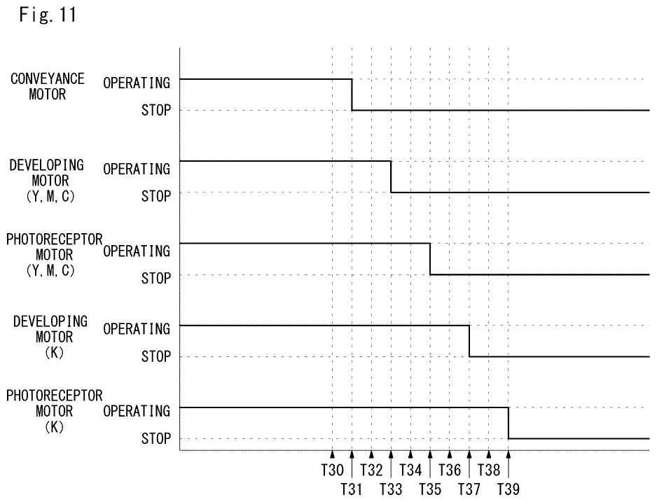

FIG. 11 is a timing chart illustrating an example of the load stop process when the conveyance motor 47 is in operation. For example, in a state where the conveyance motor 47, the photoreceptor motors 42 and 44, and the developing motors 43 and 45 are operating, the load monitoring unit 32 of the controller 30 monitors the operating states of the plurality of loads 40.

For example, the controller 30 determines that any of the loads has an abnormality at the timing T30. In that case, the controller 30 determines whether or not the conveyance motor 47 is operating, and if the conveyance motor 47 is operating, stops the conveyance motor 47 preferentially over other loads. For example, the controller 30 stops the conveyance motor 47 at the timing T31. Thus, the controller 30 prevents the occurrence of the accordion jam due to the sheet 9 being conveyed.

Upon stopping the conveyance motor 47, the controller 30 acquires the total current value I of the current flowing through the plurality of loads 40 currently operating at the timing T32 and determines whether the total current value I is within the range of the reference current value in the current operating state. In a case where the total current value I is within the range of the current reference value, the controller 30 determines that the stopped conveyance motor 47 is an abnormal load. On the other hand, when the total current value I is not within the range of the current reference value, the controller 30 determines that there is an abnormal load among the plurality of loads 40 that are currently operating.

Thereafter, the controller 30 determines whether or not there is an abnormality while stopping the photoreceptor motors 42 and 44 and the developing motors 43 and 45 one by one based on the order set in the order information 36. Note that the timings T33 to T39 illustrated in FIG. 11 are the same as the timings T2 to T8 illustrated in FIG. 5. As a result, the controller 30 can identify a load having an abnormality in the process of sequentially stopping the plurality of loads 40 one by one.

In addition, when the controller 30 sequentially stops the plurality of loads 40 in operation, if the fixing motor 46 is in operation, it is preferable to preferentially stop the fixing motor 46. In a situation in which the plurality of loads 40 are sequentially stopped, when the stopping timing of the fixing motor 46 is delayed, there is a possibility that the leading end of the sheet 9 is caught by the peeling member 8c or the switching member 18 and the accordion jam occurs in the fixing section 8. When the accordion jam occurs in the fixing section 8, it is more difficult to take out the recording medium than when the accordion jam occurs in the conveyance path 14. Therefore, when the fixing motor 46 is included in the plurality of loads 40 that are operating, the controller 30 preferably stops the fixing motor 46 with priority over the other loads. For example, when the fixing motor 46 and the conveyance motor 47 are included in the plurality of loads 40 in operation, the controller 30 preferably stops the fixing motor 46 earlier than the conveyance motor.

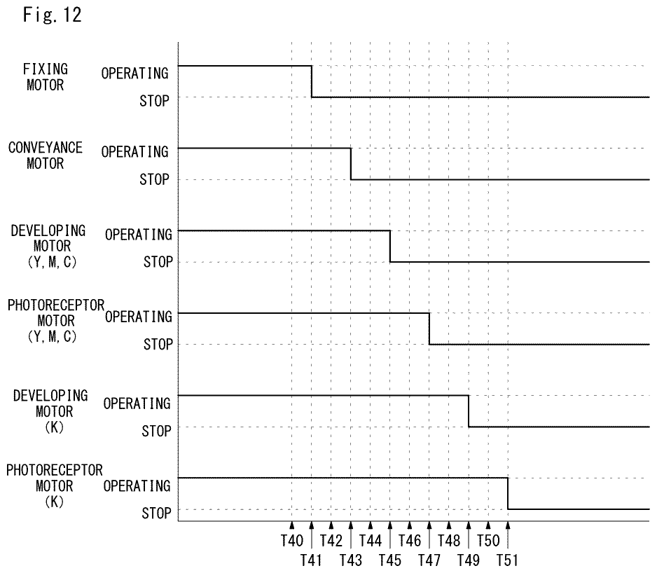

FIG. 12 is a timing chart showing an example of the load stop process when the fixing motor 46 is in operation. For example, in a state where the fixing motor 46, the conveyance motor 47, the photoreceptor motors 42 and 44, and the developing motors 43 and 45 are operating, the load monitoring unit 32 of the controller 30 monitors the operating states of the plurality of loads 40.

For example, the controller 30 determines that any of the loads has an abnormality at the timing T40. In that case, the controller 30 determines whether or not the fixing motor 46 is operating, and if the fixing motor 46 is operating, stops the fixing motor 46 preferentially over other loads. For example, the controller 30 stops the fixing motor 46 at the timing T41. Thus, the controller 30 prevents an accordion jam from occurring in the fixing section 8.

Upon stopping the fixing motor 46, the controller 30 acquires the total current value I of the current flowing through the plurality of loads 40 currently operating at the timing T42 and determines whether the total current value I is within the range of the reference current value in the current operating state. When the total current value I is within the range of the current reference value, the controller 30 determines that the stopped fixing motor 46 is an abnormal load. On the other hand, when the total current value I is not within the range of the current reference value, the controller 30 determines that there is an abnormal load among the plurality of loads 40 that are currently operating.

Next, the controller 30 determines whether or not the conveyance motor 47 is operating, and if the conveyance motor 47 is operating, stops the conveyance motor 47 preferentially over other loads. For example, the controller 30 stops the conveyance motor 47 at timing T43. As a result, the controller 30 prevents a bellows jam from occurring in the conveyance path 14.

Upon stopping the conveyance motor 47, the controller 30 acquires the total current value I of the current flowing through the plurality of loads 40 currently operating at the timing T44 and determines whether the total current value I is within the range of the reference current value in the current operating state. In a case where the total current value I is within the range of the current reference value, the controller 30 determines that the stopped conveyance motor 47 is an abnormal load. On the other hand, when the total current value I is not within the range of the current reference value, the controller 30 determines that there is an abnormal load among the plurality of loads 40 that are currently operating.

Thereafter, the controller 30 determines whether or not there is an abnormality while stopping the photoreceptor motors 42 and 44 and the developing motors 43 and 45 one by one based on the order set in the order information 36. Note that the timings T45 to T51 illustrated in FIG. 12 are the same as the timings T2 to T8 illustrated in FIG. 5. As a result, the controller 30 can identify a load having an abnormality in the process of sequentially stopping the plurality of loads 40 one by one.

As described above, the image forming apparatus 1 according to the present embodiment executes a job specified by the user by operating the plurality of loads 40. The image forming apparatus 1 includes a current detector 38 that detects a total current value I supplied from the power supply unit 37 to the plurality of loads 40 when the plurality of loads 40 are operating. In addition, the image forming apparatus 1 includes the storage section 33 that stores, for each of the operation states of the plurality of loads 40, the reference value of the current flowing through the plurality of loads 40 when each of the plurality of loads 40 is normal. Furthermore, the image forming apparatus 1 includes the controller 30 that determines whether there is an abnormality in any of the plurality of loads 40 while the plurality of loads 40 are being driven.

During the driving of the plurality of loads 40, the controller 30 compares the total current value I detected by the current detector 38 with the current reference value, and determines whether or not there is an abnormality in any of the plurality of loads 40. If determining that there is an abnormality, the controller 30 executes load stop processing for stopping the operation of the plurality of loads 40. When the operation of the plurality of loads 40 is stopped in the load stop processing, the controller 30 compares the total current value I detected by the current detector 38 with the current reference value for each operation state of the plurality of loads 40 while sequentially stopping the plurality of loads 40 one by one. Through this comparison, the controller 30 can determine whether or not the stopped load has an abnormality. When the stopped load does not have an abnormality, the plurality of loads 40 that are still operating include a load having an abnormality. Therefore, the controller 30 can identify an abnormal load by repeatedly performing the determination based on the total current value I while sequentially stopping the plurality of loads 40 one by one. That is, after detecting that there is an abnormality in any of the plurality of loads 40, the controller 30 can specify the load having the abnormality in a series of processes of stopping the plurality of loads 40.

Therefore, in a case where the image forming apparatus 1 of the present embodiment detects that there is an abnormality in any of the plurality of loads 40 in operation, the image forming apparatus 1 can identify one load having an abnormality earlier than in the related art.

In addition, when the controller 30 stops one load included in the plurality of loads 40, if the controller 30 specifies that the stopped load has an abnormality, the controller 30 collectively stops the loads in operation among the plurality of loads 40. That is, when the controller 30 specifies an abnormal load, the controller 30 does not sequentially stop the loads one by one but collectively stops the loads in operation. Therefore, when the image forming apparatus 1 specifies an abnormal load, the image forming apparatus 1 can promptly stop all operations.

A preferred embodiment of the present invention has been described above. However, the present invention is not limited to the content described in the above embodiment, and various modification examples are applicable.

For example, the load that operates during execution of a print job has been described as an example in the above embodiment. However, the loads mounted on the image forming apparatus 1 include various loads in addition to the loads described above. The above-described operation is also applicable to a case where these various loads are operating. Therefore, the load applicable in the present invention is not limited to the load described in the above embodiment.

Furthermore, the above-described embodiment illustrates, as an example, the case where the image forming apparatus 1 is configured as an MFP and is an apparatus in which a plurality of functions such as the copying function, the printing function, and the image reading function are integrated. However, the image forming apparatus 1 is not limited to one configured as an MFP. For example, the image forming apparatus 1 may be a printer having only a print function, or a scanner having only an image reader function.

In the above-described embodiment, an example in which the program 34 executed by the hardware processor of the controller 30 is stored in the storage section 33 in advance has been described. However, the program 34 can be a transaction target by itself. Therefore, the program 34 may be a program that is installed in the image forming apparatus 1 as necessary. In this case, the program 34 may be provided in a downloadable form via a network such as the Internet, or in a form recorded on a recording medium such as a CD-ROM or a USB memory.

Although embodiments of the present invention have been described and illustrated in detail, the disclosed embodiments are made for purposes of illustration and example only and not limitation. The scope of the present invention should be interpreted by terms of the appended claims.

What is claimed is

1. An image forming apparatus comprising:
a power supply unit that supplies power to a plurality of loads;
a current detector that detects a total current value supplied from the power supply to the plurality of loads;
a storage section that stores, for each operating state of the plurality of loads, a current reference value of a current that flows through the plurality of loads when each of the plurality of loads is normal; and
a controller that controls, during driving of the plurality of loads, to compare the total current value detected by the current detector with the current reference value, to determine whether or not any of the plurality of loads is abnormal, and to stop operation of the plurality of loads when determining that any of the plurality of loads is abnormal, wherein
when stopping the operation of the plurality of loads, the controller compares the total current value detected by the current detector with the current reference value for each of the operating states of the plurality of loads while stopping the plurality of loads one by one, thereby identifying a load having an abnormality.

2. The image forming apparatus according to claim 1, wherein
when one load included in the plurality of loads is stopped, if the total current value detected by the current detector matches the current reference value for each operation state of the plurality of loads, the controller specifies that the stopped one load has an abnormality.

3. The image forming apparatus according to claim 1, wherein
when one load included in the plurality of loads is stopped, if the controller specifies that the stopped load has an abnormality, the controller collectively stops loads in operation among the plurality of loads.

4. The image forming apparatus according to claim 1, wherein
the plurality of loads includes an operating time setting load for which an operating time is set in advance, and
when stopping the operation of the plurality of loads, the controller determines a stop timing of the operating time setting load based on the operation time if the operating time setting load among the plurality of loads is operating.

5. The image forming apparatus according to claim 1, wherein
the plurality of loads include a stop order setting load for which an order of stopping an operation at the time of abnormality is set in advance, and
when the operation of the plurality of loads is stopped, if the stop order setting load among the plurality of loads is operating, the controller determines the stop timing of the stop order setting load according to the order.

6. The image forming apparatus according to claim 5, wherein the stop order setting load includes:
a photoreceptor motor for driving a photoreceptor; and
a developing motor for driving a developing roller that supplies toner to the photoreceptor, and the order is an order in which the developing motor is stopped prior to the photoreceptor motor.

7. The image forming apparatus according to claim 5, wherein
the plurality of loads includes an operating time setting load for which an operating time is set in advance, and
when stopping the operation of the plurality of loads, if the operating time setting load among the plurality of loads is in operation, the controller determines the stop timing of the operating time setting load on the basis of the operation time preferentially to the order of the stop order setting load.

8. The image forming apparatus according to claim 4, wherein
the operating time setting load includes a toner replenishing motor that replenishes toner to a developing device, and
the operation time is a driving time of the toner replenishing motor for setting a toner concentration inside the developing device to a predetermined concentration.

9. The image forming apparatus according to claim 7, wherein
the operating time setting load includes a toner replenishing motor that replenishes toner to a developing device, and
the operation time is a driving time of the toner replenishing motor for setting a toner concentration inside the developing device to a predetermined concentration.

10. The image forming apparatus according to claim 1, wherein
the plurality of loads includes a conveyance motor that conveys a sheet, and
when stopping the operation of the plurality of loads, if the conveyance motor is operating, the controller stops the conveyance motor with priority over the other loads.

11. The image forming apparatus according to claim 1, wherein
the plurality of loads includes a fixing motor that drives a fixing roller, and
when stopping the operation of the plurality of loads, if the fixing motor is operating, the controller stops the fixing motor with priority over the other loads.

12. The image forming apparatus according to claim 1, further comprising:
a display part that displays various kinds of information to a user, wherein
upon identifying a load having an abnormality, the controller causes the display part to display information indicating that the identified load has an abnormality.

13. The image forming apparatus according to claim 1, further comprising:
a communication section that communicates with an external device, wherein
upon identifying a load having an abnormality, the controller notifies the external device, via the communication section, that the identified load has an abnormality.

14. A control method for controlling an image forming apparatus, the image forming apparatus including:
a power supply that supplies power to a plurality of loads;
a current detector that detects a total current value supplied from the power supply to the plurality of loads; and
a storage section that stores, for each operating state of the plurality of loads, a current reference value of a current that flows through the plurality of loads when each of the plurality of loads is normal, wherein the control method comprises:
comparing, while the plurality of loads is being driven, the total current value detected by the current detector with the current reference value to determine whether or not any of the plurality of loads is abnormal;
stopping operation of the plurality of loads when determining that any of the plurality of loads is abnormal; and
when the operation of the plurality of loads is stopped, while the plurality of loads is stopped one by one, the total current value detected by the current detector is compared with the current reference value for each of the operation states of the plurality of loads, thereby identifying a load having an abnormality.

15. A non-transitory computer-readable recording medium having recorded thereon a program to be executed in
an image forming apparatus, the image forming apparatus comprising:
a power supply that supplies power to a plurality of loads;
a current detector that detects a total current value supplied from the power supply to the plurality of loads; and
a storage section that stores, for each operating state of the plurality of loads, a current reference value of a current that flows through the plurality of loads when each of the plurality of loads is normal, wherein
the program causes the image forming apparatus to perform:
comparing, while the plurality of loads is being driven, the total current value detected by the current detector with the current reference value to determine whether or not any of the plurality of loads is abnormal;
stopping operation of the plurality of loads when determining that any of the plurality of loads is abnormal; and
when the operation of the plurality of loads is stopped, while the plurality of loads is stopped one by one, the total current value detected by the current detector is compared with the current reference value for each of the operation states of the plurality of loads, thereby identifying a load having an abnormality.
